(19) United States
(12) Patent Application Publication
(10) Pub. No.: US 2018/0204893 A1
(43) Pub. Date: Jul. 19, 2018

(54) DISPLAY DEVICE

(71) Applicant: Japan Display Inc., Tokyo (JP)

(72) Inventor: Kenta HIRAGA, Tokyo (JP)

(21) Appl. No.: 15/854,083

(22) Filed: Dec. 26, 2017

(30) Foreign Application Priority Data
Jan. 18, 2017 (JP) 2017-006516

(51) Int. Cl. H01L 27/32; H01L 51/52; G09G 3/3208

(52) U.S. Cl. CPC H01L 27/3246; G09G 2310/0264; G09G 3/3208; H01L 51/5203

(57) ABSTRACT

A display device includes pixel electrodes including first and second pixel electrodes separated from each other; a bank covering ends of the pixel electrodes and a region between the pixel electrodes, and having openings exposing the pixel electrodes; a first organic layer covering the first pixel electrode, and including a first light emitting layer; a second organic layer covering the second pixel electrode, and including a second light emitting layer; and a counter electrode covering the first and second organic layers and the bank. The first light emitting layer emits light having a first wavelength, the second light emitting layer emits light having a second wavelength longer than the first wavelength, the second organic layer is thicker than the first organic layer, and an angle made by the bank and the second pixel electrode is larger than an angle made by the bank and the first pixel electrode.

### CROSS REFERENCE TO RELATED APPLICATIONS

This application is based upon and claims the benefit of priority from the prior Japanese Patent Application No. 2017-006516, filed on Jan. 18, 2017, the entire contents of which are incorporated herein by reference.

### FIELD

An embodiment according to the present invention relates to a display device easy to be manufactured and highly reliable.

### BACKGROUND

As display devices which are usable for electric appliances and electronic devices, a liquid crystal display device using an electro-optical effect of a liquid crystal material and an organic EL (electroluminescence) display device including an organic electroluminescence (EL) element have been developed and put into actual products.

Especially in the case of being used as a display element, the organic EL element has a feature of providing a large viewing angle and high definition display. Japanese Laid-Open Patent Publication No. 2007-294421 discloses a display device including organic EL elements respectively providing a plurality of colors of light. The organic EL elements providing the plurality of colors of light each include a light emitting layer located between an anode electrode and a cathode electrode. Such light emitting layers are respectively provided for different colors of light (e.g., red (R), green (G) and blue (B)) and have different thicknesses. The organic EL elements are insulated from each other by a bank (may also be referred to as a “partitioning wall”). The organic EL elements each have an optical path length thereof adjusted accordance with the color of the light to be emitted, and thus have a light output efficiency thereof improved.

### SUMMARY

An embodiment of the present invention provides a display device including a plurality of pixel electrodes including a first pixel electrode and a second pixel electrode separated from each other; a bank covering ends of the plurality of pixel electrodes and a region between the plurality of pixel electrodes, the bank having openings exposing top surfaces of the plurality of pixel electrodes; a first organic layer covering the top surface of the first pixel electrode, the first organic layer including a first light emitting layer; a second organic layer covering the top surface of the second pixel electrode, the second organic layer including a second light emitting layer; and a counter electrode covering the first organic layer, the second organic layer and the bank. The first light emitting layer emits light having a first wavelength, the second light emitting layer emits light having a second wavelength longer than the first wavelength, the second organic layer is thicker than the first organic layer, and an angle made by a second side surface of the bank and the top surface of the second pixel electrode is larger than an angle made by a first side surface of the bank and the top surface of the first pixel electrode.

An embodiment of the present invention provides a display device including a plurality of pixel electrodes including a first pixel electrode, a second pixel electrode and a third pixel electrode separated from each other; a bank covering ends of the plurality of pixel electrodes and a region between the plurality of pixel electrodes, the bank having openings exposing top surfaces of the plurality of pixel electrodes; a first organic layer covering the top surface of the first pixel electrode, the first organic layer including a first light emitting layer; a second organic layer covering the top surface of the second pixel electrode, the second organic layer including a second light emitting layer; a third organic layer covering the top surface of the third pixel electrode, the third organic layer including a third light emitting layer; and a counter electrode covering the first organic layer, the second organic layer, the third organic layer and the bank. The first light emitting layer emits light having a first wavelength, the second light emitting layer emits light having a second wavelength longer than the first wavelength, the third light emitting layer emits light having a third wavelength longer than the second wavelength, the second organic layer is thicker than the first organic layer, the third organic layer is thicker than the second organic layer, an angle made by the bank and the top surface of the second pixel electrode is larger than an angle made by the bank and the top surface of the first pixel electrode, and an angle made by the bank and the top surface of the third pixel electrode is larger than an angle made by the bank and the top surface of the second pixel electrode.

### BRIEF EXPLANATION OF THE DRAWINGS

FIG. 1 is a plan view of a display device in an embodiment according to the present invention;

FIG. 2 is a cross-sectional view of the display device in an embodiment according to the present invention;

FIG. 3 is an enlarged view of display elements in an embodiment according to the present invention;

FIG. 4 is a cross-sectional view showing a manufacturing method for the display device in an embodiment according to the present invention;

FIG. 5 is a cross-sectional view showing the manufacturing method for the display device in an embodiment according to the present invention;

FIG. 6 is a cross-sectional view showing the manufacturing method for the display device in an embodiment according to the present invention;

FIG. 7 is a cross-sectional view showing the manufacturing method for the display device in an embodiment according to the present invention;

FIG. 8 is a cross-sectional view showing the manufacturing method for the display device in an embodiment according to the present invention;

FIG. 9 is a cross-sectional view showing the manufacturing method for the display device in an embodiment according to the present invention;

FIG. 10 is a cross-sectional view of a display device in an embodiment according to the present invention;

FIG. 11 is an enlarged view of display elements in an embodiment according to the present invention;

FIG. 12 is a cross-sectional view showing a manufacturing method for the display device in an embodiment according to the present invention;

FIG. 13 is a cross-sectional view showing the manufacturing method for the display device in an embodiment according to the present invention;

FIG. 14 is a cross-sectional view showing the manufacturing method for the display device in an embodiment according to the present invention;

FIG. 15 is a cross-sectional view showing the manufacturing method for the display device in an embodiment according to the present invention;

FIG. 16 is a cross-sectional view showing the manufacturing method for the display device in an embodiment according to the present invention;

FIG. 17 is a cross-sectional view showing the manufacturing method for the display device in an embodiment according to the present invention;

FIG. 18 is a cross-sectional view showing a display device in a modification of one of the above-described embodiments according to the present invention;

FIG. 19 is a cross-sectional view showing a display device in a modification of one of the above-described embodiments according to the present invention; and

FIG. 20 is a cross-sectional view showing a display device in a modification of one of the above-described embodiments according to the present invention.

### DESCRIPTION OF EMBODIMENTS

Hereinafter, embodiments according to the present invention will be described with reference to the drawings. This disclosure merely provides an example, and modifications or alterations thereof readily conceivable by a person of ordinary skill in the art without departing from the gist of the present invention are duly encompassed in the scope of the present invention. In the drawings, components may be shown schematically regarding the width, thickness, shape and the like, instead of being shown in accordance with the actual sizes, for the sake of clearer illustration. The drawings are merely examples and do not limit the interpretations of the present invention in any way.

In the specification and the drawings, components that have substantially the same functions as those described before with reference to a previous drawing(s) bear the identical reference signs thereto or similar reference signs thereto (for example, numerical figure “1” is put before the reference signs in the previous drawing(s) (e.g., “1130” as opposed to “130”), and detailed descriptions thereof may be omitted. The words “first”, “second” and the like provided for components are used merely to distinguish the components from each other, and do not have any further meaning unless otherwise specified.

In the specification and the claims, an expression that a component or a region is “on” another component or region encompasses a case where such a component or region is in direct contact with the another component or region and also a case where such a component is above or below the another component or region, namely, a case where still another component or region is provided between such a component or region and the another component or region, unless otherwise specified. In the following description, unless otherwise specified, the side on which a display element is provided with respect to a substrate as seen in a cross-sectional view will be referred to as “above”, and the opposite side will be referred to as “below”.

In this specification, the expressions that “a includes A, B or C”, “a includes any of A, B and C”, and “a includes one selected from the group consisting of A, B and C” do not exclude a case where a includes a plurality of combinations of A to C unless otherwise specified. The above expressions do not exclude a case where a include an element other than A, B and C.

In order to enlarge a light emitting area size of each of pixels, the bank needs to have a side surface steeply inclining. In the case where the bank has such a shape, a cathode electrode provided on an organic EL layer may be broken by the shape of the bank adjacent thereto. Therefore, conventionally, the side surface of the bank is mildly inclining, so that the breakage of the cathode electrode is avoided. However, such a mildly inclining side surface of the bank increases the total width of the bank, which decreases the light emitting area size and thus may decrease the life of the organic EL element.

A display device in an embodiment of the present invention disclosed hereinafter prevents the line breakage of a display element and has a high reliability.

### Embodiment 1

A display device 10 in this embodiment will be described with reference to the drawings.

### (1-1. Structure of the Display Device)

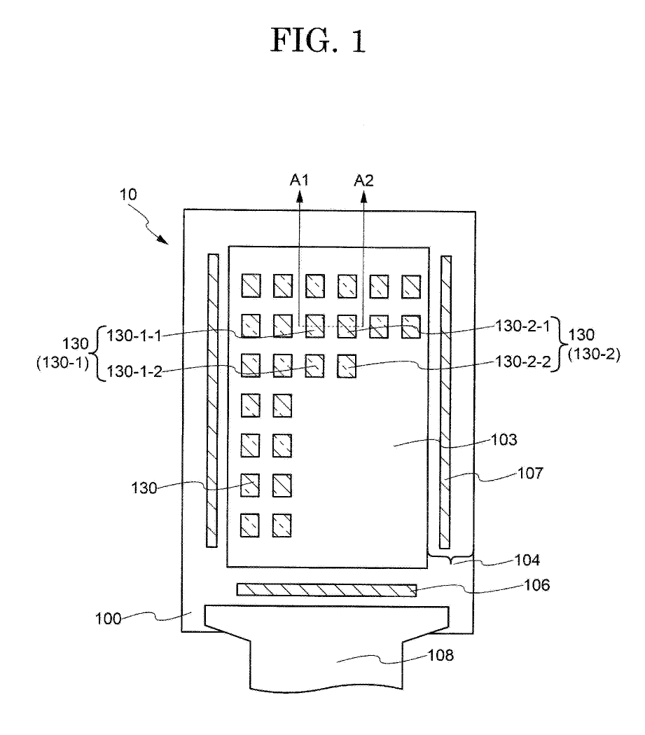

FIG. 1 is a plan view of the display device 10 in an embodiment according to the present invention. As shown in FIG. 1, the display device 10 includes a substrate 100, a display portion 103 including a plurality of display elements 130, and a peripheral portion 104 enclosing the display portion 103. The peripheral portion 104 includes a driving circuit 106 having a function of a source driver, a driving circuit 107 having a function of a gate driver, and a flexible printed circuit 108. In the display device 10, the display portion 103, the driving circuit 106, the driving circuit 107 and the flexible printed circuit 108 are electrically connected with each other. The driving circuit 106 and the driving circuit 107 are each formed of an integrated circuit such as an ASIC (Application Specific Integrated Circuit) or the like. Alternatively, the driving circuit 106 and the driving circuit 107 may each be an element directly formed on the substrate 100. The display device 10 operates as follows. An external video signal is input to the display device 10 via the flexible printed circuit 108. As a result, the driving circuit 106 and the driving circuit 107 drive the display elements 130, and thus a still image or a moving image are displayed on the display portion 103. The display elements 130 are organic EL elements. In a longer axis direction of the display portion 103, the display elements 130 displaying the same color are arrayed.

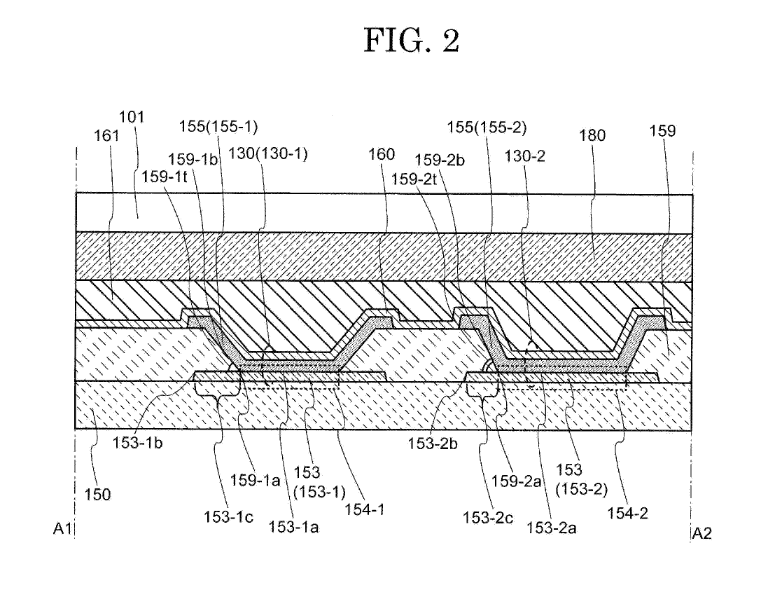

In a region shown in the cross-sectional view of FIG. 2 along line A1-A2 in FIG. 1, there are two display elements 130 (a first display element 130-1 and a second display element 130-2). For example, the first display element 130-1 is an organic EL element that emits blue or green light. A first display element 130-1-1 and a first display element 130-1-2 adjacent to the first display element 130-1-1 in the longer axis direction of the display portion 103 are organic EL elements that emit light of the same color, more specifically, blue or green light. Similarly, the second display element 130-2 is an organic EL element that emits red light. A second display element 130-2-1 and a second display element 130-2-2 adjacent to the second display element 130-2-1 in the longer axis direction of the display portion 103 are organic EL elements that emit red light.

### (1-2. Structure of the Display Elements)

FIG. 2 is a cross-sectional view of the display portion 103, more specifically, the display elements 130-1 and 130-2, taken along line A1-A2 in FIG. 1. As shown in FIG. 2, the display elements 130 include pixel electrodes 153, organic layers 155 and a counter electrode 160. One pixel electrode 153 and one organic layer 155 are provided for each of the first display element 130-1 and the second display element 130-2. The first display element 130-1 includes a first pixel electrode 153-1 and a first organic layer 155-1, and the second display element 130-2 includes a second pixel electrode 153-2 and a second organic layer 155-2. In the case where the first pixel electrode 153-1 and the second pixel electrode 153-2 do not need to be distinguished from each other, the first pixel electrode 153-1 and the second pixel electrode 153-2 may be collectively referred to as the pixel electrodes 153. In the case where the first organic layer 155-1 and the second organic layer 155-2 do not need to be distinguished from each other, the first organic layer 155-1 and the second organic layer 155-2 may be collectively referred to as the organic layers 155. In the case where the first display element 130-1 and the second display element 130-2 do not need to be distinguished from each other, the first display element 130-1 and the second display element 130-2 may be collectively referred to as the display elements 130. The display elements 130 each have a so-called top emission type structure, in which light emitted from the organic layer 155 is output toward the counter electrode 160. The display device 10 includes a thin film transistor (TFT) layer 150 including a semiconductor layer, a line layer and an insulating layer, a bank 159, a sealing layer 161, a filler 180, and a substrate 101, in addition to the display elements 130.

The pixel electrodes 153 are provided on the TFT layer 150. The pixel electrodes 153 each have a function of an electrode that drives a pixel, and preferably have a light reflecting property. For example, the pixel electrodes 153 may be formed of a light reflective metal material such as aluminum (Al), silver (Ag) or the like. Alternatively, the pixel electrodes 153 may each have a stack structure of a transparent conductive layer containing ITO (Indium Tin Oxide) or IZO (Indium Zinc Oxide) both having a superb hole injection property and a light reflective metal layer. The first pixel electrode 153-1 of the first display element 130-1 and the second pixel electrode 153-2 of the second display element 130-2 are separated from each other. Although not shown in FIG. 2, the pixel electrodes 153 are each connected with a drain electrode of the TFT layer 150 when necessary.

The bank 159 covers ends of the first pixel electrode 153-1, ends of the second pixel electrode 153-2, and a region between the first pixel electrode 153-1 and the second pixel electrode 153-2. The bank 159 has openings 154 (a first opening 154-1 and a second opening 154-2) to expose a top surface 153-1a of the first pixel electrode 153-1 and a top surface 153-2a of the second pixel electrode 153-2. The bank 159 is formed of an organic resin material. For example, the bank 159 may be formed of an acrylic resin, a polyimide resin, or the like. The bank 159 has a thickness that is appropriately set in the range of 1 μm or greater and 10 μm or less.

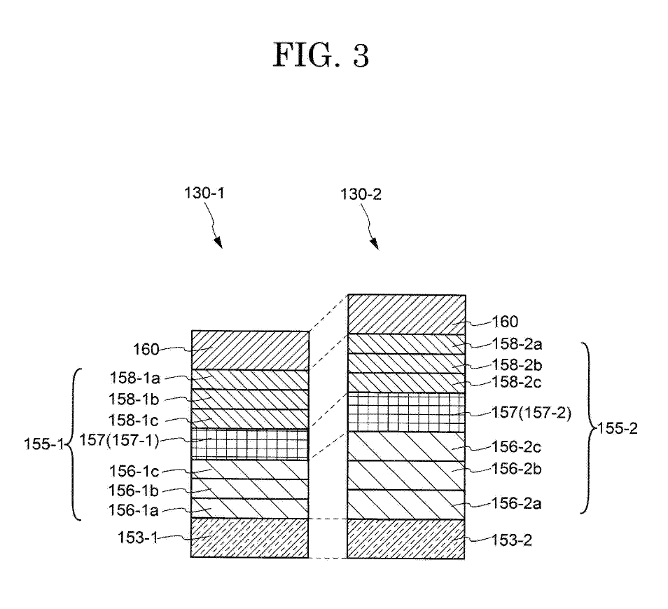

The organic layers 155 cover the top surfaces of the bank 159 and the pixel electrodes 153. In the first display element 130-1, the first organic layer 155-1 covers the top surface 153-1a of the first pixel electrode 153-1 (corresponding to the first opening 154-1). In the second display element 130-2, the second organic layer 155-2 covers the top surface 153-2a of the second pixel electrode 153-2. The organic layers 155 are selectively formed in regions separated from each other by the bank 159 and are respectively provided for the display elements 130. The organic layers 155 each include a light emitting layer 157 (see FIG. 3) containing an organic electroluminescence material or the like. The first organic layer 155-1 includes a first light emitting layer 157-1. The first light emitting layer 157-1 emits light having a first wavelength. The second organic layer 155-2 includes a second light emitting layer 157-2. The second light emitting layer 157-2 emits light having a second wavelength.

The counter electrode 160 covers the first organic layer 155-1, the second organic layer 155-2, and the bank 159. The counter electrode 160 has a function of a cathode electrode of each of the display elements 130. The counter electrode 160 has a function of reflecting a part of the light emitted by the organic layers 155 and transmitting a part of the light emitted by the organic layers 155. The counter electrode 160 is formed of a thin film of an alloy of silver (Ag) and magnesium (Mg). The counter electrode 160 is connected with a power source line having a constant potential.

Now, the first display element 130-1 and the second display element 130-2 will be compared against each other. FIG. 3 is an enlarged view of the first display element 130-1 and the second display element 130-2.

The second wavelength of the light emitted from the second light emitting layer 157-2 is longer than the first wavelength of the light emitted from the first light emitting layer 157-1. The second organic layer 155-2 is thicker than the first organic layer 155-1.

As shown in FIG. 3, the first organic layer 155-1 may include at least one of a first hole injection layer 156-1a, a first hole transfer layer 156-1b, and a first hole blocking layer 156-1c, in addition to the first light emitting layer 157-1. The first organic layer 155-1 may include at least one of a first electron injection layer 158-1a, a first electron transfer layer 158-1b, and a first electron blocking layer 158-1c. Similarly, the second organic layer 155-2 may include at least one of a second hole injection layer 156-2a, a second hole transfer layer 156-2b, and a second hole blocking layer 156-2c, in addition to the second light emitting layer 157-2. The second organic layer 155-2 may include at least one of a second electron injection layer 158-2a, a second electron transfer layer 158-2b, and a second electron blocking layer 158-2c.

The thickness of at least one of the second hole injection layer 156-2a, the second hole transfer layer 156-2b and the second hole blocking layer 156-2c included in the second organic layer 155-2 is larger than the thickness of at least one of the first hole injection layer 156-1a, the first hole transfer layer 156-1b and the first hole blocking layer 156-1c included in the first organic layer 155-1. Namely, the thickness of the second organic layer 155-2 is larger than the thickness of the first organic layer 155-1. The thickness of at least one of the second electron injection layer 158-2a, the second electron transfer layer 158-2b and the second electron blocking layer 158-2c may be larger than the thickness of at least one of the first electron injection layer 158-1a, the first electron transfer layer 158-1b and the first electron blocking layer 158-1c.

As described above, the organic layers 155 for different wavelengths of light have different thicknesses, so that the light interference effect of the pixel electrodes 153, the organic layers 155 and the counter electrode 160 is optimized. This will be described more specifically. Each of wavelengths of light has an optimal optical path length. While a part of the light is reflected between the pixel electrodes 153 and the counter electrode 160, the rest of the light is transmitted through the counter electrode 160 to be output, so that an effect of reinforcing light of a specific wavelength is provided. Such a phenomenon is referred to as a “microcavity effect”.

As shown in FIG. 2, in the first display element 130-1, the bank 159 has a first side surface 159-1b (first side surface). As seen in the cross-sectional view, an angle made by the first side surface 159-1b and the top surface 153-1a of the first pixel electrode 153-1 is labeled as a first tapering angle 159-1t. Similarly, in the second display element 130-2, the bank 159 has a second side surface 159-2b (second side surface). As seen in the cross-sectional view, an angle made by the second side surface 159-2b and the top surface 153-2a of the second pixel electrode 153-2 is labeled as a second tapering angle 159-2t. In this case, the second tapering angle 159-2t is larger than the first tapering angle 159-1t.

The bank 159 may have a curved side surface instead of a straight side surface. The bank 159 may have a side surface having a smaller tapering angle in a bottom portion thereof. Thus, the tapering angle of the side surface of the bank 159 may be an angle made by a tangential line to a middle portion of the side surface between a top surface and a bottom surface of the bank 159 and the top surface of the pixel electrode 153.

The bank 159 has the first opening 154-1at the top surface 153-1a of the first pixel electrode 153-1. A distance between a first opening end 159-1a and a first pixel electrode end 153-1b is labeled as a first distance 153-1c. Similarly, the bank 159 has the second opening 154-2 at the top surface 153-2a of the second pixel electrode 153-2. A distance between a second opening end 159-2a and a second pixel electrode end 153-2b is labeled as a second distance 153-2c. The first distance 153-1c is longer than the second distance 153-2c.

As shown in FIG. 1, a plurality of the first display elements 130-1 are provided in the longer axis direction of the display portion 103. The first display element 130-1-1 and the first display element 130-1-2 have substantially the same structure as each other in the shape of the bank 159, the thickness of the organic layer 155 and the like. Namely, among two adjacent first display elements 130-1 provided in two regions adjacent to each other, one first display element 130-1 (i.e., the first display element 130-1-1) includes one of a plurality of the first pixel electrodes 153-1. Similarly, the other of the two adjacent first display elements 130-1 (i.e., the first display element 130-1-2) includes the other of the plurality of first pixel electrodes 153-1. In this region, an angle made by a side surface (first side surface) of the bank 159 and the top surface of the one of the plurality of first pixel electrodes 153-1, and an angle made by a side surface (second side surface) of the bank 159 and the top surface of the other of the plurality of first pixel electrodes 153-1, are equal to each other. This is applicable to the second display elements 130-2.

With the above-described structure, the display elements 130 emitting different colors of light each have an optimal shape of the bank 159 and an optimal thickness of the organic layer 155. Namely, in the first display element 130-1, in which the organic layer 155 is thin, the tapering angle of the bank 159 is small. By contrast, in the second display element 130-2, in which the organic layer 155 is thick, the tapering angle of the bank 159 is large. The thickness of the organic layer 155 and the tapering angle of the bank 159 have the following relationship. In the display element 130 emitting light of a long wavelength, the thickness of the organic layer 155 is large and the tapering angle of the bank 159 is large. In the display element 130 emitting light of a short wavelength, the thickness of the organic layer 155 is small and the tapering angle of the bank 159 is small. As a result of such an arrangement, the coverage of the counter electrode 160 on the side surface of the bank 159 is increased, and therefore, the breakage of the counter electrode 160 provided on the organic layer 155 is prevented in the entire region of the display portion 103. In the second display element 130-2, the tapering angle of the bank 159 is maximized. Therefore, the top surface of the bank 159 between two adjacent display elements 130 is made large. As a result, even in the case where different organic materials are vapor-deposited, the organic materials are merely vapor-deposited on the top surface of the bank 159. Therefore, an organic material unnecessary for the second display device 130-2 is prevented from being incorporated. Since the tapering angle of the bank 159 is maximized in the second display device 130-2, the light emitting area size is enlarged. This suppresses the second organic layer 155-2 from being deteriorated by application of an electric current, which extends the life of the second display element 130-2. The tapering angle of the bank 159 with which the light emitting area size is guaranteed to be a certain level with no breakage may be appropriately set in the range of 30 degrees or greater and less than 70 degrees.

### (1-3. Method for Manufacturing the Display Device)

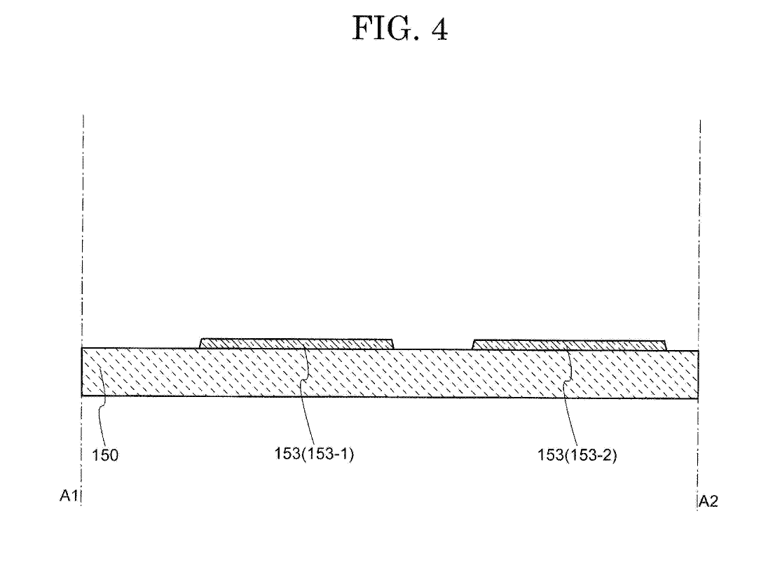

Now, a method for manufacturing the display device 10 will be described with reference to FIG. 4 to FIG. 9. First, as shown in FIG. 4, the pixel electrodes 153 (the first pixel electrode 153-1 and the second pixel electrode 153-2) are formed on a flattened surface of the TFT layer 150. The pixel electrodes 153 are formed by sputtering, vacuum vapor deposition, plating or the like. The pixel electrodes 153 may be formed to have a predetermined shape when necessary by photolithography, nanoimprinting, ink-jetting, etching or the like. Although not shown, the pixel electrodes 130 are each connected with a line extending from the TFT layer 150.

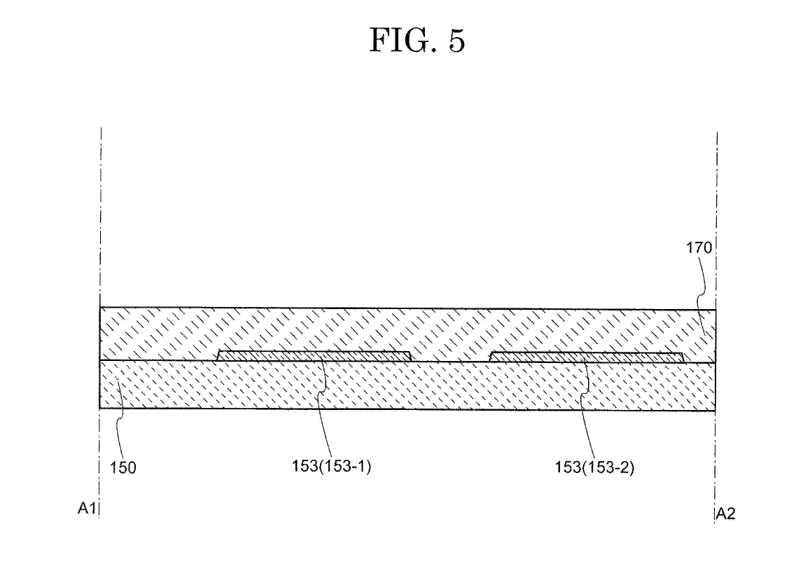

Next, as shown in FIG. 5, an organic film 170, which is to become the bank 159, is formed. The organic film 170 is formed by spin-coating, ink-jetting, lamination, dip-coating or the like. The organic film 170 is formed of an organic resin material. For example, the organic film 170 is formed of an acrylic resin, a polyimide resin or the like. The organic film 170 may contain a photosensitive material.

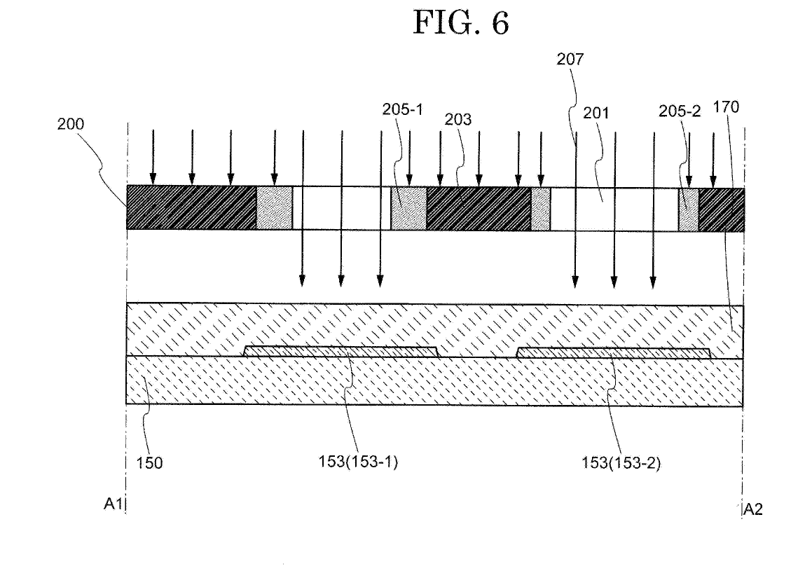

The organic film 170 is processed by photolithography. For being processed, the organic film 170 may be exposed to light by use of a half-one mask 200 as shown in FIG. 6. The half-tone mask 200 includes a transmissive portion 201, a light-blocking portion 203 and a semi-transmissive portion 205. The half-tone mask 200 includes first semi-transmissive portions 205-1 in portions facing the ends of the first pixel electrode 153-1. Similarly, the half-tone mask 200 includes second semi-transmissive portions 205-2 in portions facing the ends of the second pixel electrode 153-2. The second semi-transmissive portion 205-2 has a width smaller than that of the first semi-transmissive portion 205-1.

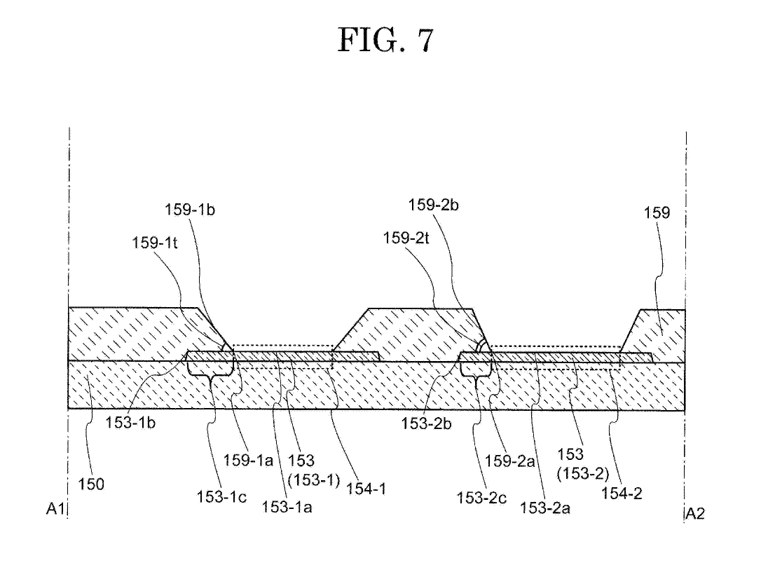

After being exposed to light by use of the half-tone mask 200, the organic film 170 is developed to form the bank 159 as shown in FIG. 7. The bank 159 has the first tapering angle 159-1t on the first pixel electrode 153-1. The bank 159 has the second tapering angle 159-2t on the second pixel electrode 153-2.

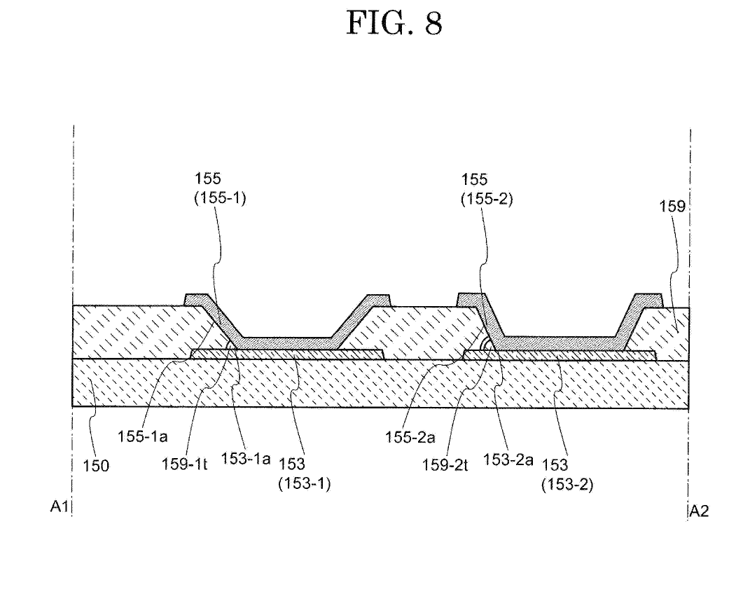

Next, as shown in FIG. 8, the organic layers 155 (the first organic layer 155-1 and the second organic layer 155-2) are formed. The organic layers 155 are formed by vacuum vapor deposition, coating or ink-jetting. The first organic layer 155-1 and the second organic layer 155-2 are formed separately. In the case where, for example, the organic layers 155 are formed by vacuum vapor deposition, a shadow mask is used.

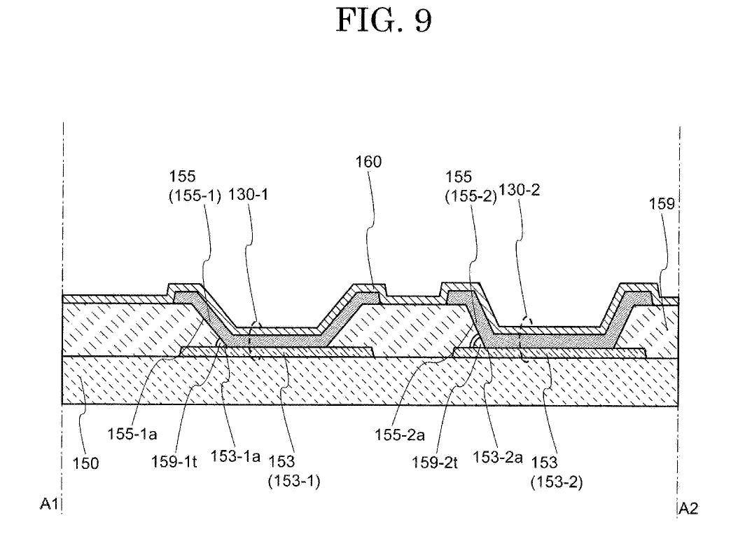

Next, as shown in FIG. 9, the counter electrode 160 is formed on the bank 159 and the organic layers 155. The counter electrode 160 is formed by sputtering or physical vapor deposition. The counter electrode 160 is formed of a semi-transmissive metal material. For example, the counter electrode 160 is formed of an alloy of silver and magnesium. As a result, the display elements 130 (the first display element 130-1 and the second display element 130-2) are formed. The sealing layer 161, the filler 180 and the substrate 101 are further formed, and the display device 10 is manufactured.

### Embodiment 2

### (2-1. Structure of the Display Elements)

A case where there are three different display elements will be described below. The structures and methods described in embodiment 1 are also applicable to this embodiment. In order to be distinguished from those in embodiment 1, the display elements will be labeled as “1130” in this embodiment.

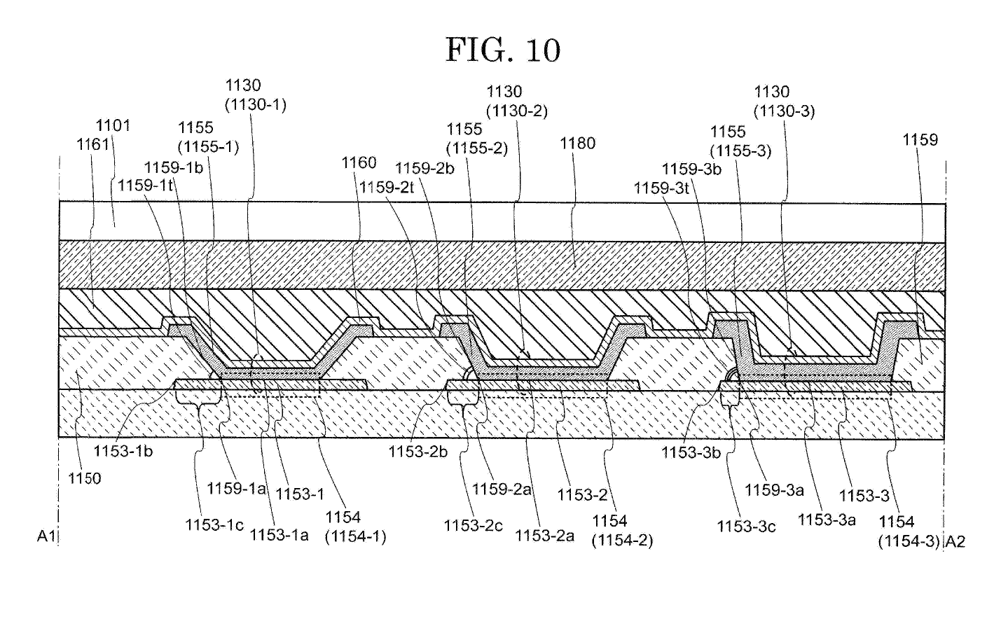

FIG. 10 is a cross-sectional view of display portions 1103 in this embodiment. FIG. 10 corresponds to the cross-sectional view taken along line A1-A2 in FIG. 1. In a region corresponding to the region shown in the cross-sectional view of FIG. 2 along line A1-A2 in FIG. 1, there are three display elements 1130 (a first display element 1130-1, a second display element 1130-2, and a third display element 1130-3) taken along line A1-A2. The first display element 1130-1 is a light emitting element that emits blue light. The second display element 1130-2 is a light emitting element that emits green light. The third display element 1130-3 is a light emitting element that emits red light. The display elements 1130 include pixel electrodes 1153, organic layers 1155, and a counter electrode 1160.

The pixel electrodes 1153 are each formed on a TFT layer 1150 including thin film transistors. A first pixel electrode 1153-1 of the first display element 1130-1, a second pixel electrode 1153-2 of the second display element 1130-2, and a third pixel electrode 1153-3 of the third display element 1130-3 are separated from each other. The pixel electrodes 1153 are each connected with a power source line having a constant potential.

A bank 1159 is provided on the TFT layer 1150 and the pixel electrodes 1153. The bank 1159 covers ends of the first pixel electrode 1153-1, ends of the second pixel electrode 1153-2, ends of the third pixel electrode 1153-3, and regions between the first pixel electrode 1153-1, the second pixel electrode 1153-2 and the third pixel electrode 1153-3. The bank 159 has openings 1154 (a first opening 1154-1, a second opening 1154-2, and a third opening 1154-3) to expose a top surface 1153-1a of the first pixel electrode 1153-1, a top surface 1153-2a of the second pixel electrode 1153-2, and a top surface 1153-3a of the third pixel electrode 1153-3.

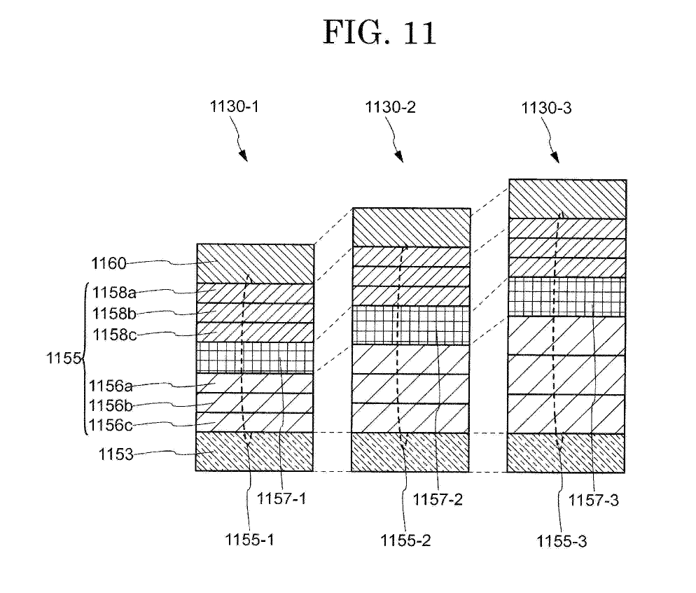

The organic layers 1155 cover the stop surfaces of the bank 1159 and the pixel electrodes 1153. In the first display element 1130-1, the first organic layer 1155-1 covers the top surface 1153-1a of the first pixel electrode 1153-1 (corresponding to the first opening 1154-1). In the second display element 1130-2, the second organic layer 1155-2 covers the top surface 1153-2a of the second pixel electrode 1153-2. In the third display element 1130-3, the third organic layer 1155-3 covers the top surface 1153-3a of the third pixel electrode 1153-3. The organic layers 1155 are respectively provided for the display elements 1130 and are separated from each other by the bank 1159. The first organic layer 1155-1 includes a first light emitting layer 1157-1as shown in FIG. 11. The first light emitting layer 1157-1 emits light having a first wavelength. The second organic layer 1155-2 includes a second light emitting layer 1157-2 as shown in FIG. 11. The second light emitting layer 1157-2 emits light having a second wavelength. The third organic layer 1155-3 includes a third light emitting layer 1157-3 as shown in FIG. 11. The third light emitting layer 1157-3 emits light having a third wavelength.

The counter electrode 1160 covers the first organic layer 1155-1, the second organic layer 1155-2, the third organic layer 1155-3, and the bank 1159.

Now, the first display element 1130-1, the second display element 1130-2 and the third display element 1130-3 will be compared against each other. FIG. 11 is an enlarged view of the first display element 1130-1, the second display element 1130-2 and the third display element 1130-3.

The second wavelength of the light emitted from the second light emitting layer 1157-2 is longer than the first wavelength of the light emitted from the first light emitting layer 1157-1. The third wavelength of the light emitted from the third light emitting layer 1157-3 is longer than the second wavelength of the light emitted from the second light emitting layer 1157-2. The second organic layer 1155-2 is thicker than the first organic layer 1155-1. The third organic layer 1155-3 is thicker than the second organic layer 1155-2.

As shown in FIG. 11, the organic layers 1155 may each include at least one of a hole injection layer 1156a, a hole transfer layer 1156b, and a hole blocking layer 1156c, in addition to the light emitting layer 1157. The organic layers 1155 may each include at least one of an electron injection layer 1158a, an electron transfer layer 1158b, and an electron blocking layer 1158c.

As shown in FIG. 10, in the first display element 1130-1, the bank 1159 has a first side surface 1159-1b. An angle made by the first side surface 1159-1b and the top surface 1153-1a of the first pixel electrode 1153-1 is labeled as a first tapering angle 1159-1t. Similarly, in the second display element 1130-2, the bank 1159 has a second side surface 1159-2b. An angle made by the second side surface 1159-2b and the top surface 1153-2a of the second pixel electrode 1153-2 is labeled as a second tapering angle 1159-2t. Similarly, in the third display element 1130-3, the bank 1159 has a third side surface 1159-3b. An angle made by the third side surface 1159-3b and the top surface 1153-3a of the third pixel electrode 1153-3 is labeled as a third tapering angle 1159-3t. In this case, the second tapering angle 1159-2t is larger than the first tapering angle 1159-1t. The third tapering angle 1159-3t is larger than the second tapering angle 1159-2t.

The bank 1159 may have a curved side surface instead of a straight side surface. The bank 1159 may have a side surface having a smaller tapering angle in a bottom portion thereof. Thus, the tapering angle of the side surface of the bank 1159 may be an angle made by a tangential line to a middle portion of the side surface between a top surface and a bottom surface of the bank 1159 and the top surface of the pixel electrode 1153.

The bank 1159 has the first opening 1154-1at the top surface 1153-1a of the first pixel electrode 1153-1. A distance between a first opening end 1159-1a of the first opening 1154-1 and a first pixel electrode end 1153-1b of the first pixel electrode 1153-1 is labeled as a first distance 1153-1c. Similarly, the bank 1159 has the second opening 1154-2 at the top surface 1153-2a of the second pixel electrode 1153-2. A distance between a second opening end 1159-2a of the second opening 1154-2 and a second pixel electrode end 1153-2b of the second pixel electrode 1153-2 is labeled as a second distance 1153-2c. Similarly, the bank 1159 has the third opening 1154-3 at the top surface 1153-3a of the third pixel electrode 1153-3. A distance between a third opening end 1159-3a of the third opening 1154-3 and a third pixel electrode end 1153-3b of the third pixel electrode 1153-3 is labeled as a third distance 1153-3c. The first distance 1153-1c is longer than the second distance 1153-2c. The second distance 1153-2c is longer than the third distance 1153-3c.

With the above-described structure, the display elements 1130 emitting different colors of light each have an optimal shape of the bank 1159 and an optimal thickness of the organic layer 1155. Namely, in the first display element 1130-1, in which the organic layer 1155 is thinnest, the tapering angle of the bank 1159 is smallest. By contrast, in the third display element 1130-3, in which the organic layer 1155 is thickest, the tapering angle of the bank 1159 is largest. In the second display element 1130-2, the tapering angle of the bank 1159 and the thickness of the organic layer 1155 are between those of the first display element 1130-1 and those of the third display element 1130-3. As a result of such an arrangement, the coverage of the counter electrode 1160 on the side surface of the bank 1159 is increased, and therefore, the breakage of the counter electrode 1160 is prevented in each of the display elements 1130. In the third display element 1130-3, the light emitting area size is enlarged, and therefore, the third organic layer 1155-3 is suppressed from being deteriorated. In the third display element 1130-3, the tapering angle of the bank 1159 is maximized. Therefore, the top surface of the bank 1159 between two adjacent display elements 1130 is made large. As a result, even in the case where different organic materials are vapor-deposited, the organic materials are merely vapor-deposited on the top surface of the bank 1159. Therefore, an organic material unnecessary for the second display element 1130-2 is prevented from being incorporated.

Although not shown, a plurality of the first display elements 1130-1 are provided in the longer axis direction of the display portion 1103. Two first display elements 1130 provided in such adjacent regions have the following relationship. One of the first display elements 1130-1 includes one of a plurality of the first pixel electrodes 1153-1. Similarly, the other of the first display elements 1130-1 includes the other of the plurality of first pixel electrodes 1153-1. In this region, an angle made by a side surface of the bank 1159 and the top surface of the one of the plurality of first pixel electrodes 1153-1, and an angle made by a side surface of the bank 1159 and the top surface of the other of the plurality of first pixel electrodes 1153-1, are equal to each other. This is applicable to the second display elements 1130-2 and the third display elements 1130-3.

### (2-2. Method for Manufacturing the Display Device)

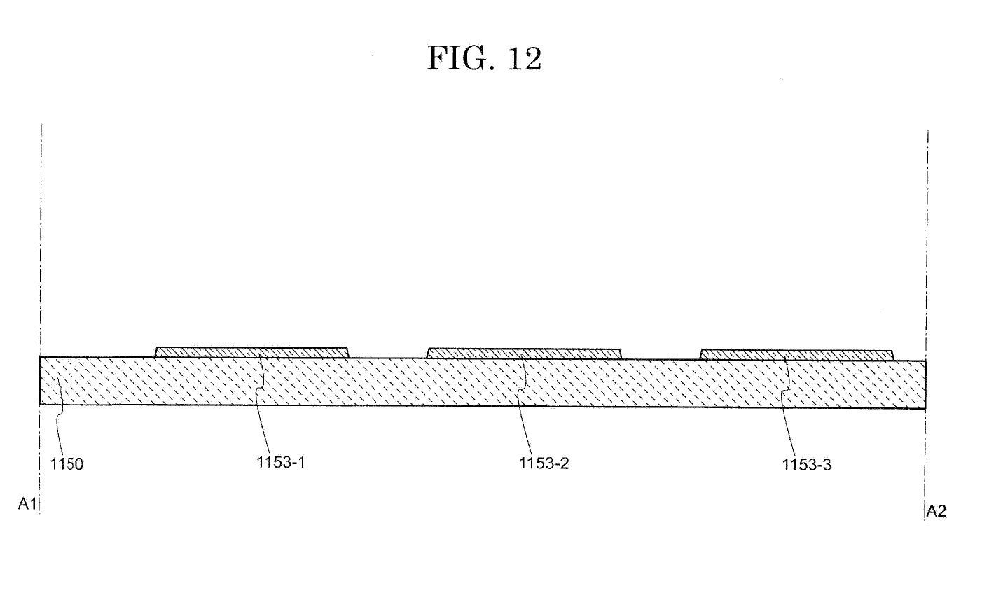

Now, a method for manufacturing the display device, especially, the display elements 1130, will be described with reference to FIG. 12 to FIG. 17.

First, as shown in FIG. 12, the pixel electrodes 1153 (the first pixel electrode 1153-1, the second pixel electrode 1153-2 and the third pixel electrode 1153-3) are formed on a flattened surface of the TFT layer 1150.

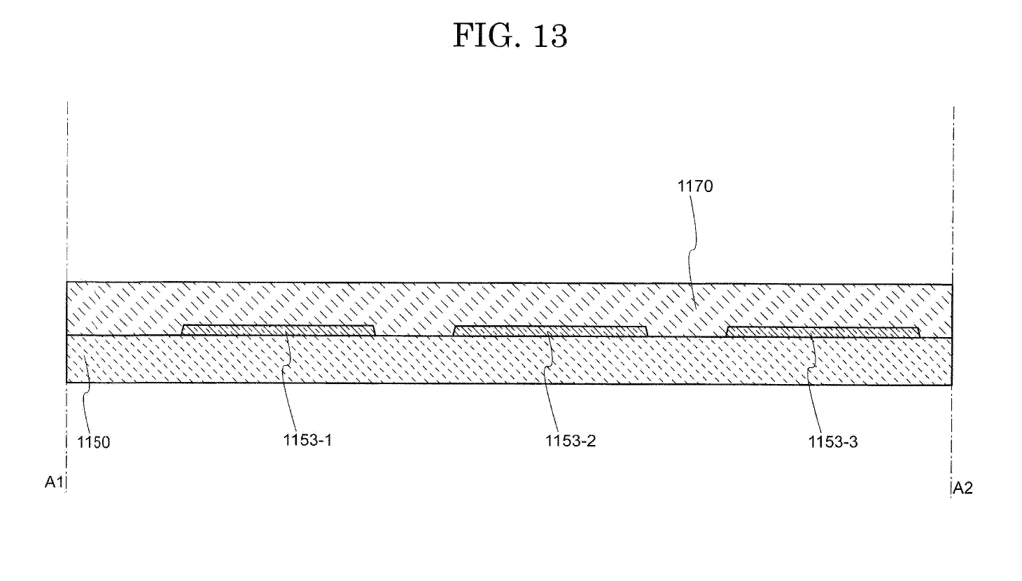

Next, as shown in FIG. 13, an organic film 1170, which is to become the bank 1159, is formed.

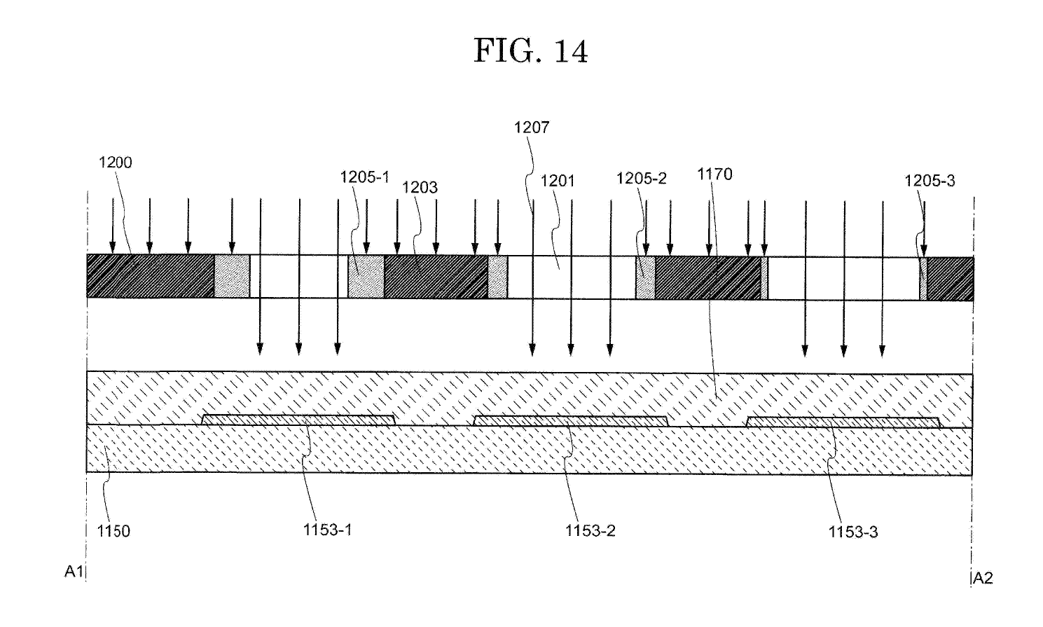

The organic film 1170 is processed by photolithography. As shown in FIG. 14, a half-one mask 1200 is used in photolithography. The half-tone mask 1200 includes semi-transmissive portions 1205-1 in portions facing the ends of the first pixel electrode 1153-1. Similarly, the half-tone mask 1200 includes semi-transmissive portions 1205-2 in portions facing the ends of the second pixel electrode 1153-2. Similarly, the half-tone mask 1200 includes semi-transmissive portions 1205-3 in portions facing the ends of the third pixel electrode 1153-3. The first semi-transmissive portion 1205-1 has a width larger than that of the first semi-transmissive portion 1205-2. The second semi-transmissive portion 1205-2 has a width larger than that of the third semi-transmissive portion 1205-3.

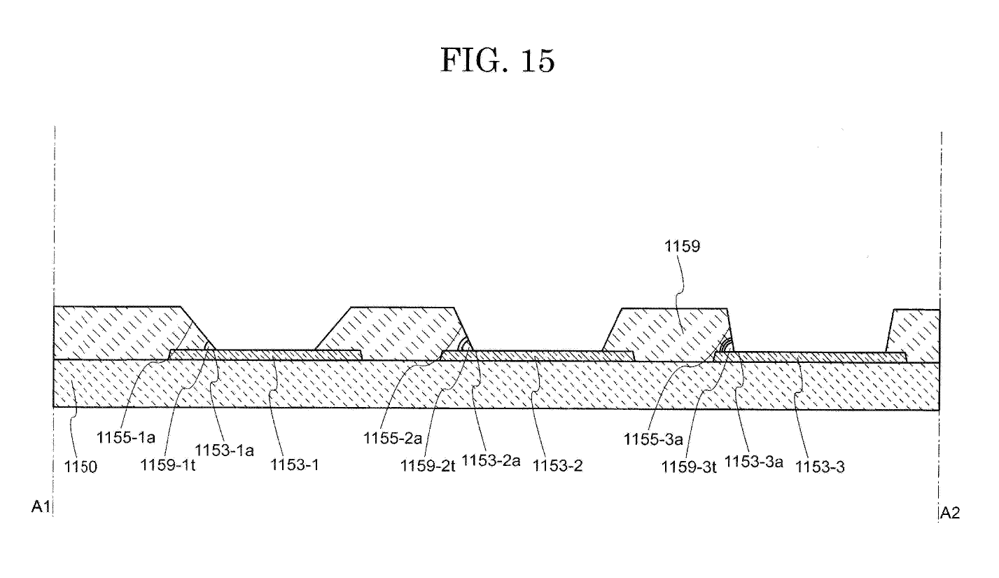

After being exposed to light by use of the half-tone mask 1200, the organic film 1170 is developed to form the bank 1159 as shown in FIG. 15. The bank 1159 has the first tapering angle 1159-1t on the first pixel electrode 1153-1. The bank 1159 has the second tapering angle 1159-2t on the second pixel electrode 1153-2. The bank 1159 has the third tapering angle 1159-3t on the third pixel electrode 1153-3.

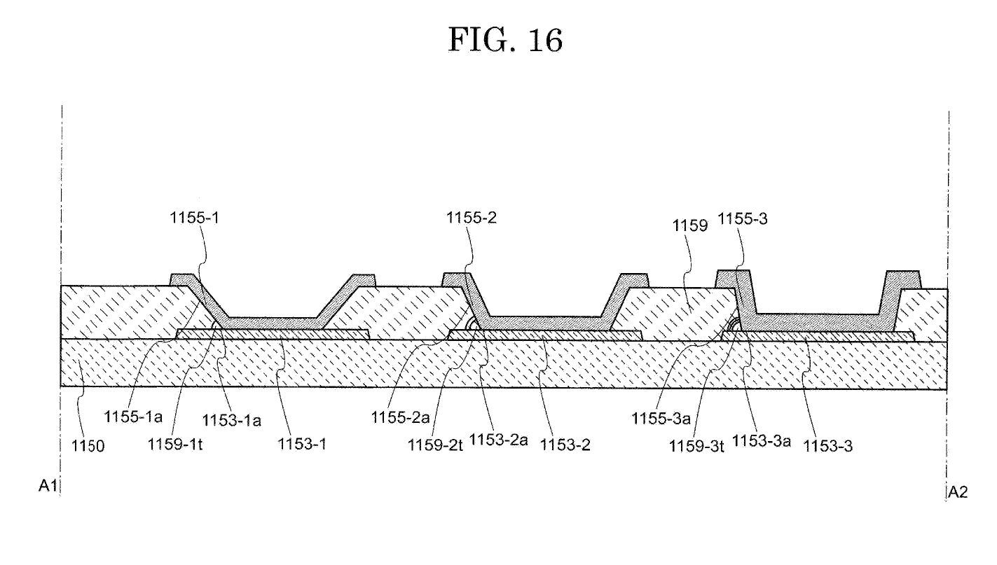

Next, as shown in FIG. 16, the organic layers 1155 (the first organic layer 1155-1, the second organic layer 1155-2 and the third organic layer 1155-3) are formed. The first organic layer 1155-1, the second organic layer 1155-2 and the third organic layer 1155-3 are formed separately.

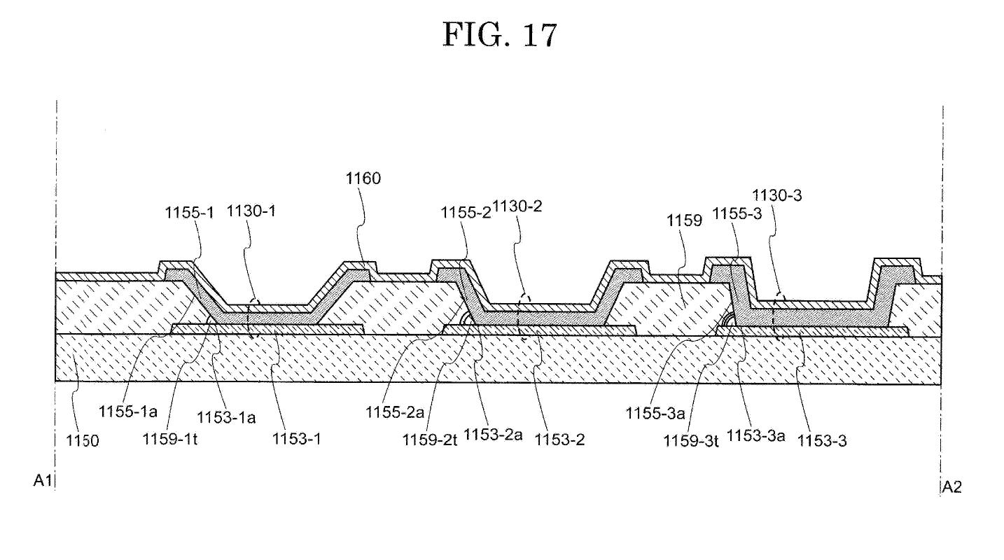

Next, as shown in FIG. 17, the counter electrode 160 is formed on the bank 1159, the first organic layer 1155-1, the second organic layer 1155-2 and the third organic layer 1155-3. As a result, the display elements 130 are formed.

### <Modifications>

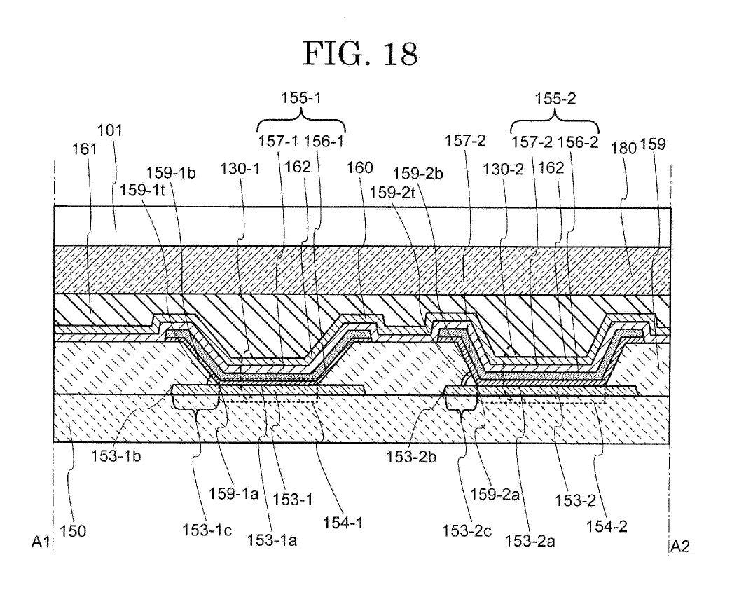

In embodiment 1 of the present invention, the first organic layer 155-1 and the second organic layer 155-2 are formed separately. In the case where the first organic layer 155-1 and the second organic layer 155-2 are formed of the same material, a common layer 162 may be formed continuously on the first organic layer 155-1 and the second organic layer 155-2 as shown in FIG. 18. The common layer 162 may include at least one of a hole injection layer, a hole transfer layer, a hole blocking layer, an electron injection layer, an electron transfer layer and an electron blocking layer. For example, as shown in FIG. 18, a first layer 156-1 including at least one of the first hole injection layer 156-1a, the first hole transfer layer 156-1b and the first hole blocking layer 156-1c (see FIG. 3) and the first light emitting layer 157-1 are provided separately from a second layer 156-2 including at least one of the second hole injection layer 156-2a, the second hole transfer layer 156-2b and the second hole blocking layer 156-2c (see FIG. 3) and the second light emitting layer 157-2. The common layer 162 including at least one of the electron injection layer, the electron transfer layer and the electron blocking layer is provided continuously on the first light emitting layer 157-1 and the second light emitting layer 157-2.

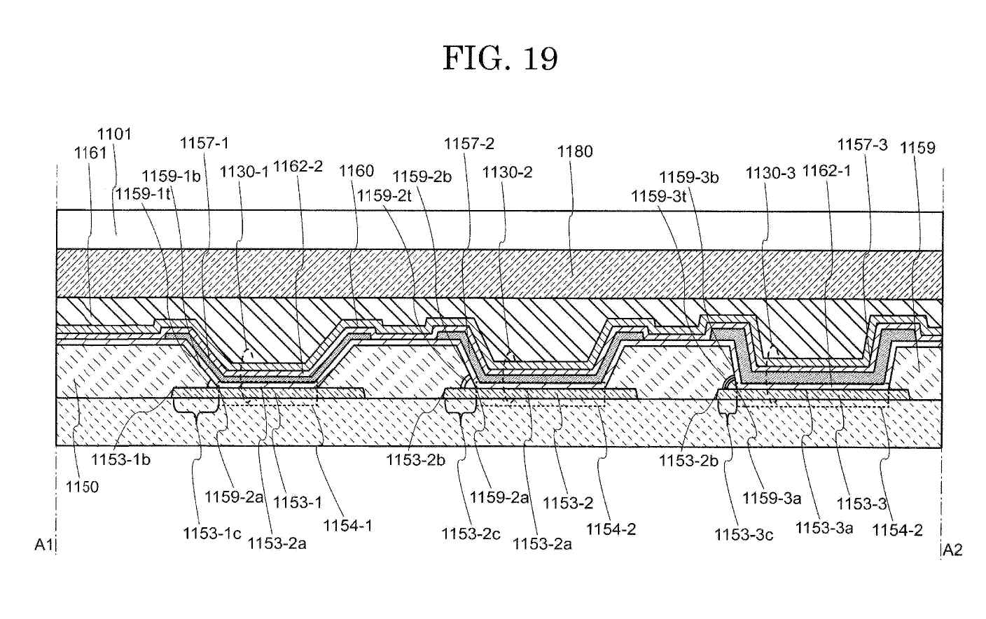

Similarly, as shown in FIG. 19, a first common layer 1162-1 and a second common layer 1162-2 may be formed continuously on the first light emitting layer 1157-1, the second light emitting layer 1157-2 and the third light emitting layer 1157-3. As shown in FIG. 19, the first light emitting layer 1157-1, the second light emitting layer 1157-2 and the third light emitting layer 1157-3 are formed separately. The first common layer 1162-1 including at least one of the hole injection layer 1156a, the hole transfer layer 1156b and the hole blocking layer 1156c (see FIG. 11), and the second common layer 1162-2 including at least one of the electron injection layer 1158a, the electron transfer layer 1158b and the electron blocking layer 1158c (see FIG. 11) are provided continuously on the first light emitting layer 1157-1 and the second light emitting layer 1157-2. Such a structure simplifies the manufacturing method and thus decreases the manufacturing cost. The simplification of the manufacturing method improves the throughput and increases the yield of the products.

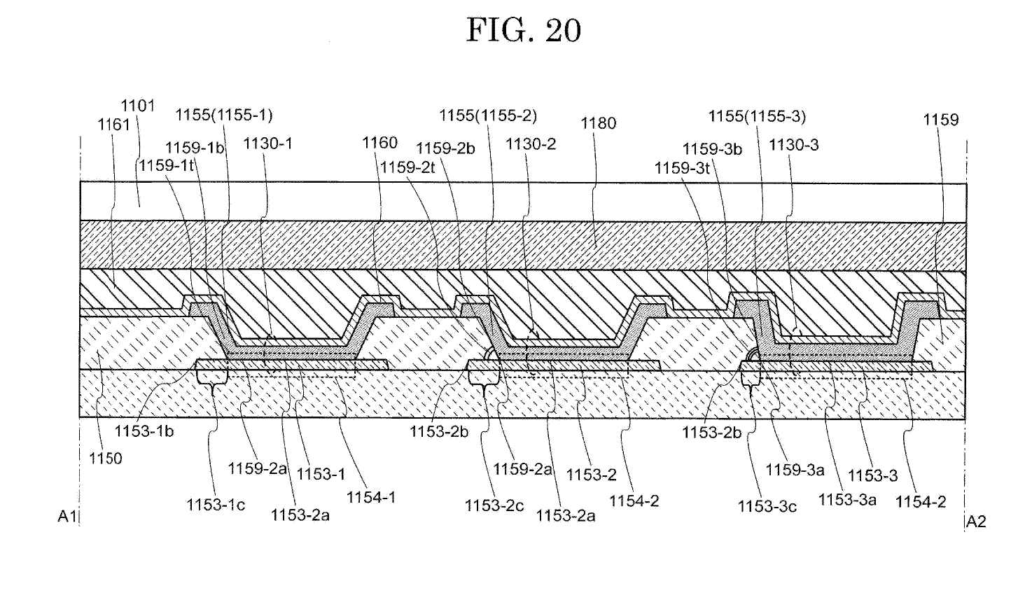

In embodiment 2 of the present invention, three display elements respectively include organic layers of different thicknesses. As shown in FIG. 20, the first organic layer 1155-1 and the second organic layer 1155-2 may have the same thickness as each other. In this case, the third organic layer 1155-3 is thicker than each of the first organic layer 1155-1 and the second organic layer 1155-2. In the case where the organic layers 1155 in the three display elements 1130 do not need to have different thicknesses from each other, two of the display elements 1130 may be manufactured at the same time with such a structure. This simplifies the manufacturing method and thus decreases the manufacturing cost. The simplification of the manufacturing method improves the throughput and increases the yield of the products.

A person of ordinary skill in the art would readily conceive various alterations or modifications of the present invention, and such alterations and modifications are construed as being encompassed in the scope of the present invention. For example, the display devices in the above-described embodiments may have an element added thereto, or deleted therefrom, or may be changed in design optionally by a person of ordinary skill in the art. The methods in the above-described embodiments may have a step added thereto, or deleted therefrom, or may be changed in the condition optionally by a person of ordinary skill in the art. Such devices and methods are encompassed in the scope of the present invention as long as including the gist of the present invention.

What is claimed is:

1. A display device, comprising:
a plurality of pixel electrodes including a first pixel electrode and a second pixel electrode separated from each other;
a bank covering ends of the plurality of pixel electrodes and a region between the plurality of pixel electrodes, the bank having openings exposing top surfaces of the plurality of pixel electrodes;
a first organic layer covering the top surface of the first pixel electrode, the first organic layer including a first light emitting layer;
a second organic layer covering the top surface of the second pixel electrode, the second organic layer including a second light emitting layer; and
a counter electrode covering the first organic layer, the second organic layer and the bank, wherein
the first light emitting layer emits light having a first wavelength,
the second light emitting layer emits light having a second wavelength longer than the first wavelength,
the second organic layer is thicker than the first organic layer, and
an angle made by a second side surface of the bank and the top surface of the second pixel electrode is larger than an angle made by a first side surface of the bank and the top surface of the first pixel electrode.

2. The display device according to claim 1, wherein a first distance between an end of a first opening, among the openings, of the bank on the top surface of the first pixel electrode and an end of the first pixel electrode is longer than a second distance between an end of a second opening, among the openings, of the bank on the top surface of the second pixel electrode and an end of the second pixel electrode.

3. The display device according to claim 1, further comprising a common layer continuously provided on the first organic layer and the second organic layer.

4. The display device according to claim 1, wherein
the plurality of pixel electrodes include a plurality of the first pixel electrodes, and
in a region where one of the first pixel electrodes and the other of the first pixel electrodes are adjacent to each other, an angle made by a first side surface of the bank and the top surface of the one of the first pixel electrodes is equal to an angle made by a first side surface of the bank and the top surface of the other of the first pixel electrodes.

5. The display device according to claim 4, wherein
the plurality of pixel electrodes include a plurality of the second pixel electrodes, and
in a region where one of the second pixel electrodes and the other of the second pixel electrodes are adjacent to each other, an angle made by a second side surface of the bank and the top surface of the one of the second pixel electrodes is equal to an angle made by a second side surface of the bank and the top surface of the other of the second pixel electrodes.

6. A display device, comprising:
a plurality of pixel electrodes including a first pixel electrode, a second pixel electrode and a third pixel electrode separated from each other;
a bank covering ends of the plurality of pixel electrodes and a region between the plurality of pixel electrodes, the bank having openings exposing top surfaces of the plurality of pixel electrodes;
a first organic layer covering the top surface of the first pixel electrode, the first organic layer including a first light emitting layer;
a second organic layer covering the top surface of the second pixel electrode, the second organic layer including a second light emitting layer;
a third organic layer covering the top surface of the third pixel electrode, the third organic layer including a third light emitting layer; and
a counter electrode covering the first organic layer, the second organic layer, the third organic layer and the bank, wherein
the first light emitting layer emits light having a first wavelength,
the second light emitting layer emits light having a second wavelength longer than the first wavelength,
the third light emitting layer emits light having a third wavelength longer than the second wavelength,
the second organic layer is thicker than the first organic layer,
the third organic layer is thicker than the second organic layer,
an angle made by the bank and the top surface of the second pixel electrode is larger than an angle made by the bank and the top surface of the first pixel electrode, and
an angle made by the bank and the top surface of the third pixel electrode is larger than an angle made by the bank and the top surface of the second pixel electrode.

7. The display device according to claim 6, wherein
a first distance between an end of the opening of the bank at the top surface of the first pixel electrode and an end of the first pixel electrode is longer than a second distance between an end of the opening of the bank at the top surface of the second pixel electrode and an end of the second pixel electrode, and
the second distance is longer than a third distance between an end of the opening of the bank at the top surface of the third pixel electrode and an end of the third pixel electrode.

8. The display device according to claim 7, further comprising a common layer continuously provided on the first organic layer, the second organic layer and the third organic layer.

9. The display device according to claim 6, wherein
the plurality of pixel electrodes include a plurality of the first pixel electrodes, and
in a region where one of the first pixel electrodes and the other of the first pixel electrodes are adjacent to each other, an angle made by a side surface of the bank and the top surface of the one of the first pixel electrodes is equal to an angle made by a side surface of the bank and the top surface of the other of the first pixel electrodes.

10. The display device according to claim 9, wherein
the plurality of pixel electrodes include a plurality of the second pixel electrodes, and
in a region where one of the second pixel electrodes and the other of the second pixel electrodes are adjacent to each other, an angle made by a side surface of the bank and the top surface of one of the second pixel electrodes is equal to an angle made by a side surface of the bank and the top surface of the other of the second pixel electrodes.

11. The display device according to claim 10, wherein
the plurality of pixel electrodes include a plurality of the third pixel electrodes, and
in a region where one of the third pixel electrodes and the other of the third pixel electrodes are adjacent to each other, an angle made by a side surface of the bank and the top surface of one of the third pixel electrodes is equal to an angle made by a side surface of the bank and the top surface of the other of the third pixel electrodes.

12. The display device according to claim 3, wherein the common layer includes at least one of a hole injection layer, a hole transfer layer, a hole blocking layer, an electron injection layer, an electron transfer layer, and an electron blocking layer.

13. The display device according to claim 8, wherein the common layer includes at least one of a hole injection layer, a hole transfer layer, a hole blocking layer, an electron injection layer, an electron transfer layer, and an electron blocking layer.
